(19) United States
(12) Patent Application Publication
(10) Pub. No.: US 2008/0265955 A1
(43) Pub. Date: Oct. 30, 2008

(54) SYNCHRONIZATION CIRCUIT AND METHOD

(76) Inventor: Abhay Kejriwal, Wiltshire (GB)

Correspondence Address: DICKSTEIN SHAPIRO LLP, 1825 EYE STREET NW, Washington, DC, 20006-5403, US

(21) Appl. No.: 12/109,875

(22) Filed: Apr. 25, 2008

(30) Foreign Application Priority Data
Apr. 25, 2007 (GB) 0708049.2

(51) Int. Cl. H03L 7/00

(52) U.S. Cl. 327/144

(57) ABSTRACT

An integrated circuit comprises a system clock and an interface clock. A synchronizing circuit is provided for synchronizing a control signal associated with a predetermined command, for example a PENABLE signal associated with a WRITE command, when the system clock of the integrated circuit is present and bypassing the synchronization circuitry when the system clock is not present. Thus, whenever the system clock of the integrated circuit is active, all the control interface write operations are synchronized to the system clock, and hence there are no timing issues due to different clock domains. If the system clock is not present, the asynchronous writes cannot cause any timing problems, and the synchronization circuit is therefore bypassed.

### BACKGROUND OF THE INVENTION

1. Field of the Invention

The invention relates to a synchronization circuit and method, and in particular to a synchronization circuit and method for selectively providing synchronization in a system comprising first and second clock signals.

2. Description of the Related Art

Various standards have been developed for enabling communication between two or more integrated circuits (ICs). One such standard is a simple bi-directional 2-wire bus for efficient inter-IC control, known as the “Inter-IC bus” (or I²C™ bus). At present, the I²C™ bus can be used to perform communication functions between intelligent control devices (e.g. microcontrollers), general-purpose circuits (e.g. LCD drivers, audio circuits, remote I/O ports, memories) and application-oriented circuits (e.g. digital tuning and signal processing circuits for audio and video systems). Devices that are I²C™ bus compatible incorporate an on-chip interface control circuit that allows the devices to communicate directly with each other via the I²C™ bus.

FIG. 1 shows an integrated circuit 1, for example a mixed-signal integrated circuit, comprising an interface control circuit 3 for interfacing with a communication link such as the I²C™ bus. The interface control circuit 3 receives control signals, for example an external (to the integrated circuit 1) interface clock signal 13 and an external data signal 12 when interfacing with an I²C™ bus. Signals received via the interface control circuit 3 are used to configure the integrated circuit 1 in a desired mode of operation. An interface control circuit 3 for an I²C™ bus will output various internal signals to control various internal registers. In an example of one such scheme, the interface control circuit 3 may output the following signals: a PENABLE signal; a PWRITE signal; a MW_BUSY signal; a DATA signal; and an address signal ADDR. Ideally the interface control circuit 3 is configured to use the minimum number of pins possible for communicating with other integrated circuits (for example 2 pins for the I²C™ bus). This is because additional pins have the disadvantages of requiring additional circuitry (for example bond pads) and larger packages. It is also desirable to reduce the number of control lines between integrated circuits in order to reduce the susceptibility of the communication link to disturbances by Electromagnetic Interference (EMI) and Electrostatic Discharge (ESD).

It will be appreciated by a person skilled in the art that many other industry standard communication links exist, including other 2-wire and 3-wire control interfaces such as the serial peripheral interface (SPI). SPI is used primarily for a synchronous serial communication of a host processor and peripherals.

These types of control interfaces allow the programming of one or more internal registers 5 within the integrated circuit 1. The one or more internal registers 5 control the various operational modes of system blocks 11 provided in the integrated circuit 1. The internal registers 5 may comprise latches and/or flip-flops.

An inherent problem with such interface control circuits 3 is that the interface clock 13 (i.e. external clock) is totally asynchronous to an internal/externally generated system clock 15 that controls the system blocks 11 (i.e. digital circuitry) within the integrated circuit 1. Existing interface control circuits 3 are flexible in that that they can work with a range of different frequencies but only up to a specified maximum. In an interface control circuit 3, the interface clock 13 is only guaranteed to be present during an “access”, for example a write operation. As the interface control circuit 3 writes to the internal registers 5 of the integrated circuit, the timing of the corresponding register bits are relative to the external interface clock 13.

As mentioned above, the system clock 15 for controlling the integrated circuit 1 may be an internally generated clock signal (i.e. on-chip) or an externally generated clock signal received from another source (not illustrated). During a time when the interface control circuit 3 writes register bits to the internal registers 5, the system clock 15 may or may not be present. The presence of the system clock 15 creates timing problems because the internal registers 5 are within the time domain of the external interface clock 13, whereas the control of the system blocks is within the time domain of the system clock 15. These timing problems can lead to improper operation of the integrated circuit 1 if not handled correctly.

Traditionally, the output of the internal registers 5 is synchronized to the system clock 15 using a synchronizing circuit 9 placed between the internal registers 5 and the system blocks 11. Synchronization of the interface clock 13 with the system clock 15 typically involves the use of two synchronization flip-flops per register bit so as to avoid metastability problems. Such problems could lead to high current consumption and incorrect operation. In state-of-the-art systems on integrated circuits the number of “configuration bits” stored in the internal registers 5 may be quite large and could even run into thousands of bits. Thus, it will be appreciated that providing two synchronization flip-flops per register bit has the disadvantage of increasing the die size, power consumption and cost of the integrated circuit.

Another problem that may occur, even after synchronization, relates to the buses. Different data bits present on the buses (multiple bit registers) may have a one-cycle delay between each other. The result of this one-cycle delay could be catastrophic depending on the usage of these data bits. Generally, a complex scheme is required in the on-chip control circuit 7 to avoid problems occurring due to these one-cycle delay issues. Such a scheme requires updating of the synchronizing circuit 9 when it is safe to do so, i.e. when all the individual data bits are stable, and this requires extra logic which further increases die size, power consumption etc. For example, a voltage converter may have a 6 bit register for controlling voltage settings. The voltage converter may have a present setting of 011111, for example, which needs to be re-programmed to a setting of 100000. If the delays are different between the data bits, the voltage converter may have a setting of 111111 for the duration of the synchronization delay before arriving at the correct setting of 100000. This could result in a catastrophic event such as an extreme over voltage, which might destroy the system.

Furthermore, in complex systems the configuration bits stored in the internal registers 5 may require modifying by the system blocks 11 within the integrated circuit 1 (i.e. separately or in addition to being modified by the interface control circuit 3). For example, in a power management system, a power converter can be enabled by writing a logic ‘1’ to the appropriate configuration control bit. Depending on the system conditions, a configuration control bit of a power converter might also be able to be modified by an internal state-machine in, for example, the case of a fault condition such as overload. Such a system could lead to a situation where the interface control circuit 3 and the internal state machine within the system blocks 11 are both trying to modify the same bit within the internal registers 5 simultaneously. This in turn could lead to timing problems and operational hazards which could actually cause incorrect operation due to metastability issues. The synchronization of the internal signals of an integrated circuit 1 back to the time domain of the interface clock 13 is not always possible since the interface clock 13 may not be present. This would require an even more complex solution per signal thus increasing silicon area and power consumption even further.

### SUMMARY OF THE INVENTION

According to a first aspect of the invention, there is provided a synchronization circuit for an integrated circuit, the integrated circuit having at least one system block operating in synchronization with a first clock signal. The synchronizing circuit comprises: a first input for receiving a control signal that is synchronized with a second clock signal; synchronizing means for synchronizing the control signal with the first clock signal to generate a modified control signal; and selecting means configured to selectively output either the control signal or the modified control signal according to the status of the first clock signal.

The synchronizing circuit defined above has the advantage of synchronizing a control signal, for example a write command, when a first clock (e.g. system clock) of the integrated circuit is present and effectively bypassing the synchronization circuitry when the first clock is not present.

Thus, whenever the system clock of the integrated circuit is active, all the control interface write operations, for example, are synchronized to the system clock, and hence there are no timing issues due to different clock domains. If the system clock is not present, the asynchronous writes cannot cause any timing problems, and the synchronization circuit is therefore bypassed.

As such, the synchronization flip flops of the prior art are completely removed and only the write command is synchronized.

According to another aspect of the invention, there is provided a method of synchronizing the operation of an integrated circuit having at least one system block operating in synchronization with a first clock signal. The method comprises the steps of: receiving a control signal that is synchronized with a second clock signal; synchronizing the control signal with the first clock signal to generate a modified control signal; and selectively outputting either the control signal or the modified control signal according to the status of the first clock signal.

### BRIEF DESCRIPTION OF THE DRAWINGS

For a better understanding of the present invention, and to show more clearly how it may be put into effect, reference will now be made by way of example only to the accompanying drawings in which:

FIG. 1 shows block diagram of a known synchronization circuit for interfacing between an internal clock and an external clock;

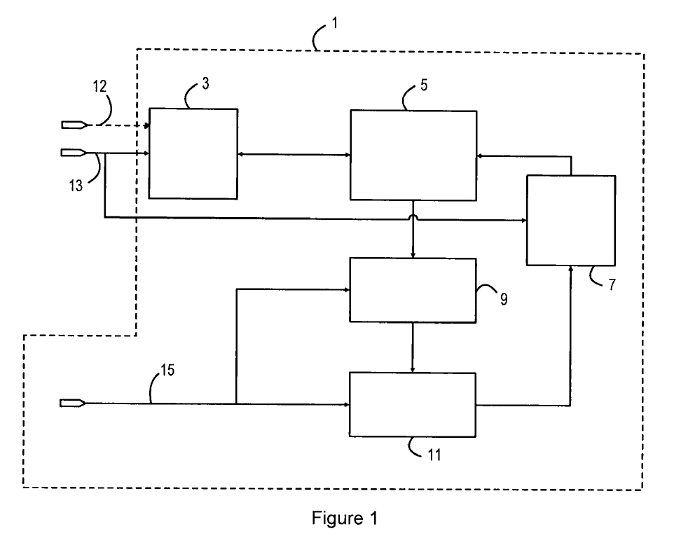

FIG. 2 shows a conceptual block diagram of a synchronizing circuit according to a first embodiment of the present invention;

FIG. 3 shows a more detailed schematic diagram of the synchronizing circuit illustrated in FIG. 2 according to one example embodiment; and

FIG. 4 illustrates the signal waveforms of the synchronizing circuit shown in FIG. 3.

### DETAILED DESCRIPTION OF THE PREFERRED EMBODIMENT

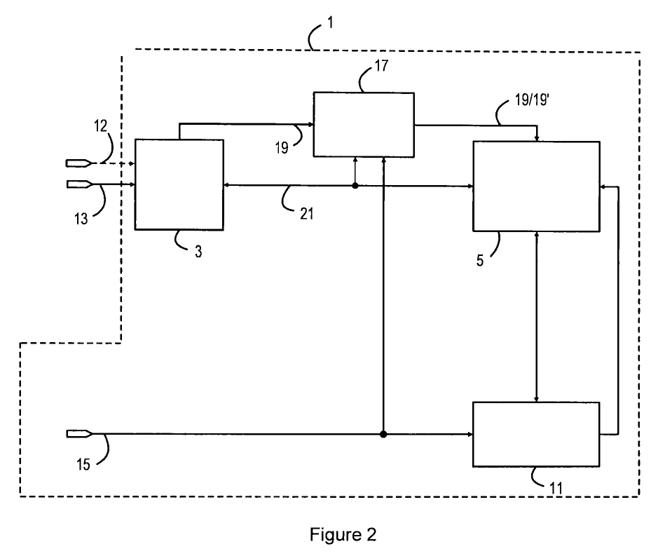

FIG. 2 shows a synchronizing circuit 17 for an integrated circuit 1, the integrated circuit comprising an interface control circuit 3, one or more internal registers 5 and one or more system blocks 11. The system blocks 11 are controlled by a system clock 15. Although not illustrated, the system clock 15 may be an internally generated clock signal (i.e. one that is generated on-chip) or an externally generated clock signal (i.e. one that is received from an external source).

The interface control circuit 3 is shown as being connected to an I²C™ bus, thus receiving an external interface clock signal 13 and an external interface data signal 12. It will be appreciated that, although the present embodiment is being described in relation to a 2-wire I²C™ bus system, the invention is equally applicable to other n-wire communication links having an interface clock 13 and a system clock 15 (where n is an integer of three or more).

The interface control circuit 3 is shown as having first and second input/output signal lines 19, 21. The first signal line 19 receives a control signal in the form of a PENABLE signal from the interface control circuit 3. The second signal line 21 represents multiple signal lines corresponding to PWRITE, MW_BUSY, ADDR, or DATA signals received from the interface control circuit 3. Further explanation of these signals will be given below. Although not shown, it will be appreciated that the interface control circuit 3 may comprise one or more other input/output signal lines.

The PWRITE and PENABLE signals, respectively, determine whether it is a write operation or a read operation that is being performed on the internal registers 5. The PWRITE signal is a static signal during an access operation, while the PENABLE signal pulses, i.e. is a dynamic signal, during a READ/WRITE operation. The MW_BUSY signal indicates whether the interface control circuit 3 is carrying out an access or not with the internal registers 5. The ADDR signal acts as the address bus for indicating which register of the internal registers 5 is to be written to or read from. The DATA signal line acts as the data bus containing the data to be written to the register 5.

The synchronizing circuit 17 is configured to receive the PENABLE signal 19 and the PWRITE signal 21 from the interface control circuit 3, together with the system clock 15. The synchronizing circuit 17 comprises synchronizing means for synchronizing the PENABLE signal 19 with the system clock 15, thereby generating a modified version of the control signal PENABLE that is synchronized with the system clock. The synchronizing circuit 17 is configured to selectively output either the original PENABLE signal 19 or a modified PENABLE signal 19′ (i.e. the synchronized PENABLE signal 19′) according to the status of the system clock 15, for example whether or not the system clock 15 is present, or the status of the write signal PWRITE. As such, the output from the synchronizing circuit 17 is either a PENABLE signal 19′ which is synchronized with respect to the external interface clock 13, or an asynchronous version of the PENABLE signal 19 (i.e. not synchronized with the external interface clock 13).

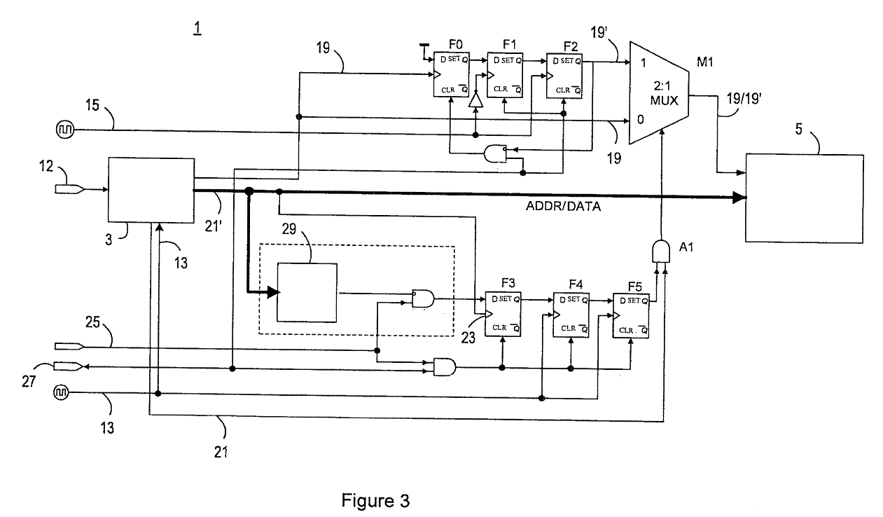

A more detailed explanation of the synchronizing circuit is given below with reference to FIG. 3. It will be appreciated that other circuit arrangements may be used to achieve the function provided by the circuit of FIG. 3. In addition, references to certain circuit components such as flip-flops, muliplexers or AND gates may be realised by other circuit components providing the same function.

FIG. 3 shows an integrated circuit 1 having an interface control circuit 3 (for example an I²C™ interface), and one or more internal registers 5. The interface control circuit 3 receives external interface data 12 and an external interface clock 13. Signal line 15 represents the system clock 15 (which is either generated internally or externally). Signal line 25 represents an OSC_GOOD signal that indicates whether the system clock 15 is present or not. Signal line 27 represents a power-on-reset signal POR.

Signal line 19 is connected to the interface control circuit 3 and provides a PENABLE signal to the clock input of a first flip-flop F0. The PENABLE signal is also connected to a first input of a 2:1 multiplexer M1 (i.e. input “0”). Signal line 21′ provides the ADDR, and DATA signals for the internal registers 5, and the MW_BUSY signal for the clock input 23 of flip-flop F3. The ADDR signal from the interface control circuit 3 selects a particular register in the internal registers 5. Its associated data signal DATA contains the data to be written to the selected register.

An inverted version of the system clock 15 is connected to a clock input of a second flip-flop F1, with the system clock 15 also being connected directly (i.e. non-inverted) to a clock input of a third flip-flop F2. The output of the first flip-flop F0 is connected to the input of the second flip-flop F1, with the output of the second flip-flop F1 being connected to the input of the third flip-flop F2. The output of the third flip-flop F2 is in turn connected to the second input of the 2:1 multiplexer M1.

As mentioned above, the signal MW_BUSY connected to the clock input 23 of the flip-flop F3 indicates whether the interface control circuit 3 is carrying out an access or not. On the rising edge of this MW_BUSY signal, the status of the internal clock is captured in flip-flop F3, i.e. using the status of the OSC_GOOD signal 25 connected to the data input of the flip-flop F3. The captured state of the system clock 15 is then synchronized to the interface clock signal 13 using flip-flops F4 and F5.

An AND gate A1 receives the output of flip-flop F5 and the PWRITE signal 21. The output of AND gate A1 determines whether the output from the multiplexer M1 is the synchronized version of the PENABLE signal 19′ (i.e. the output of flip-flop F2 connected to the second input “1” of the multiplexer M1) or the asynchronous version of the PENABLE signal 19 (i.e. the first input “0” to the multiplexer M1 received directly from the interface control circuit 3).

If the system clock 15 is absent during a synchronous write it will be indicated by the OSC_GOOD signal 25 which will reset the flip-flops F3 to F5 and will cause the system to choose asynchronous writes via the AND gate A1 and multiplexer M1.

The synchronous version of the PENABLE signal 19′ is obtained as follows. The PENABLE signal 19 is captured using flip-flop F0 in order to take care of the case when the frequency of the interface clock 13 is larger than the frequency of the system clock 15. The PENABLE signal 19 is then synchronized with the system clock 15 using flip-flops F1 and F2. The rising edge of the PENABLE signal is latched using flip-flop F0. Flip-flops F1 and F2 are run on opposite clock edges to each other so as to improve the throughput of the system. For example, flip-flop F1 may run on the −ve edge of the system clock 15 (i.e. the clock that is being synchronized with), while the flip-flop F2 runs on the +ve edge of the system clock 15. Using the opposite, i.e. +ve and −ve, clock edges in flip-flops F1 and F2 means that the synchronizing circuit has the advantage of only requiring 1½ system clocks to operate, rather than 2 system clocks if both F1 and F2 used the same clock edge. Therefore, in the example above, the output of flip-flop F2 will go high about 1½ system clock cycles after the PENABLE signal has gone high.

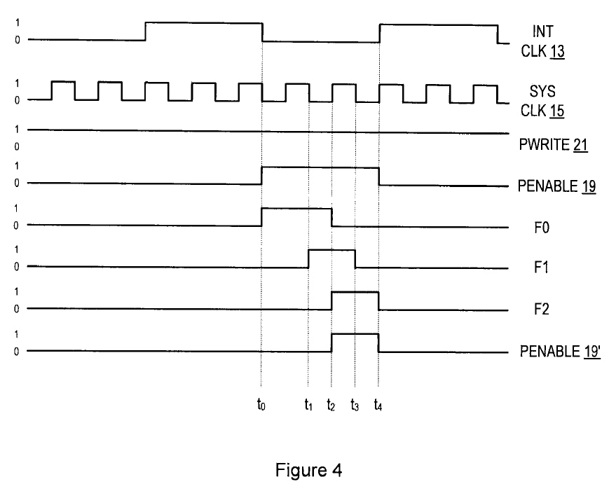

The timing waveforms corresponding to the circuit operation described above are shown in FIG. 4. The PENABLE signal 19 is captured using flip-flop F0 at time t₀. The PENABLE signal 19 is then synchronized with the system clock 15 using flip-flops F1 and F2. The rising edge of the PENABLE signal 19 is latched using flip-flop F0. In the example of FIG. 4, flip-flop F1 is run on the −ve edge of the system clock 15 (i.e. the clock that is being synchronized with) as shown at time t₁, while the flip-flop F2 runs on the +ve edge of the system clock 15, as shown at time t₂. As mentioned above, using the opposite, i.e. +ve and −ve, clock edges in flip-flops F1 and F2 means that the synchronizing circuit has the advantage of only requiring 1 1/1 system clocks to operate, rather than 2 system clocks if both F1 and F2 used the same clock edge. The synchronized PENABLE signal 19′ has a rising edge and falling edge corresponding to the rising edge and falling edge of flip-flop F2 at times t₂ and t₄, respectively. As such, the PENABLE signal 19′ is synchronized with the system clock 15. It will be appreciated that, although FIG. 4 shows the system clock 15 and interface clock 13 as being substantially in synchronization for clarity of explanation, in reality the system clock 15 and interface clock 13 will most likely be out of synchronization.

The output of flip-flop F2 (i.e. synchronized version of the PENABLE signal 19′) and the unsynchronized version of the PENABLE signal 19 are connected to the first and second inputs of the 2:1 multiplexer M1 which is appropriately controlled using the AND gate A1 so as to select the required version of the PENABLE signal. The multiplexer M1 therefore acts as a selecting means for selectively outputting either the synchronous or asynchronous version of the control signal PENABLE 19′/19, respectively, depending on the presence or absence of the system clock 15.

When, for example, the PWRITE signal is at logic “0” and the PENABLE signal at logic “1”, this implies that a read operation is being performed on an internal register 5. In this case the output of AND gate A1 will be “0” which selects the asynchronous PENABLE signal 19 connected to the first input (input “0”) of the multiplexer M1. Since the integrated circuit 1 cannot control the interface timing, the integrated circuit 1 has to pass data back to the interface control circuit 3 using the time domain of the interface clock 13. Hence the use of the asynchronous PENABLE signal 19 is required in this case.

Thus, when the PWRITE signal is at logic “1” and the PENABLE signal at logic “1′”, this implies that a write operation is being performed on an internal register 5. In this case the output of AND gate A1 will be ‘1’ if the system clock 15 is present. As a result, the AND gate A1 selects the synchronized version of the PENABLE signal 19′ (i.e. the output of flip-flop F2) and carries out a synchronous write to the register bits. If the system clock 15 was not present and the output of the AND gate were a logic “0”, an asynchronous write would be selected. Hence a write will be performed even if the system clock 15 is not present.

The synchronizing circuit described above has the advantage of performing a synchronous write operation when the system clock is present, and an asynchronous write operation when the system clock is absent, or when a different command such as a read command is being performed.

It will be appreciated that the arrangement above places a constraint on the frequencies of the interface clock 13 and the system clock 15.

For example, if “Fscl” is the frequency of the interface clock 13 and “Fsysclk” is the frequency of the system clock 15, with say “N” being the number of interface clock cycles required to perform a write, then, in this case:

Fsysclk>=N/3×Fscl

(assuming that the address and data is not changed until the next write is needed).

It can be seen that the invention provides a simple, low cost, method for synchronizing an operation such as a write operation in an integrated circuit 1 having an internal system clock and an external clock.

Audio applications of the present invention include portable devices (MP3 players; mobile phones; personal computers, laptops, PDAs and satellite navigation devices); Hi-Fi equipment including disk-based players such as DVD/CD; televisions; and digital cameras (Still & Video). In addition, the present invention may find application in fixed or semi-fixed installations such as in-car entertainment, aircraft on-board entertainment systems and so forth.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

What is claimed is:

1. A synchronizing circuit for an integrated circuit, the integrated circuit having at least one system block operating in synchronization with a first clock signal, the synchronizing circuit comprising:
a first input for receiving a control signal that is synchronized with a second clock signal;
synchronizing means for synchronizing the control signal with the first clock signal to generate a modified control signal; and
selecting means configured to selectively output either the control signal or the modified control signal according to the status of the first clock signal.

2. A synchronizing circuit as claimed in claim 1, wherein the selecting means is configured to output the modified control signal when the first clock signal is present.

3. A synchronizing circuit as claimed in claim 1, wherein the selecting means is configured to output the modified control signal when a predetermined command is being performed.

4. A synchronizing circuit as claimed in claim 1, further comprising logic means for controlling the operation of the selecting means.

5. A synchronizing circuit as claimed in claim 4, wherein the logic means comprises an AND gate.

6. A synchronizing circuit as claimed in claim 4, wherein the logic means is connected to receive a signal indicating the presence or absence of the first clock signal.

7. A synchronizing circuit as claimed in claim 4, wherein the logic means is connected to receive a signal indicating the presence or absence of the predetermined command.

8. A synchronizing circuit as claimed in claim 1, wherein the synchronizing means for synchronizing the control signal with the first clock signal comprises:
a first flip-flop connected to receive the control signal as a clock signal, the first flip-flop having a data input connected to logic 1;
a second flip-flop connected to receive an inverted version of the first clock signal as its clock signal, the second flip-flop having its input connected to the output of the first flip-flop; and
a third flip-flop connected to receive the first clock signal as its clock signal, the third flip-flop having its input connected to the output of the second flip-flop, and the output of the third flip-flop providing the modified control signal to the selecting means.

9. A synchronizing circuit as claimed in claim 1, wherein the selecting means comprises a 2:1 multiplexer.

10. A synchronizing circuit as claimed in claim 1, wherein the control signal is a PENABLE control signal associated with a write command.

11. A synchronizing circuit as claimed in claim 1, wherein the first clock signal is a system clock of the integrated circuit.

12. A synchronizing circuit as claimed in claim 1, wherein the second clock signal is an interface clock of an interface associated with the integrated circuit.

13. A method of synchronizing the operation of an integrated circuit having at least one system block operating in synchronization with a first clock signal, the method comprising the steps of:
receiving a control signal that is synchronized with a second clock signal;
synchronizing the control signal with the first clock signal to generate a modified control signal; and
selectively outputting either the control signal or the modified control signal according to the status of the first clock signal.

14. A method as claimed in claim 13, wherein the step of selectively outputting either the control signal or the modified control signal comprises the step of outputting the modified control signal when the first clock signal is present.

15. A method as claimed in claim 13, wherein the step of selectively outputting either the control signal or the modified control signal comprises the step of outputting the modified control signal when a predetermined command is being performed.

16. A method as claimed in claim 13, wherein the synchronizing step comprises the steps of:
connecting a first flip-flop to receive the control signal as a clock signal, the first flip-flop having a data input connected to logic 1;
connecting a second flip-flop to receive an inverted version of the first clock signal as its clock signal, the second flip-flop having its input connected to the output of the first flip-flop; and
connecting a third flip-flop to receive the first clock signal as its clock signal, the third flip-flop having its input connected to the output of the second flip-flop, and the output of the third flip-flop providing the modified control signal to the selecting means.

17. A method as claimed in claim 13, wherein the control signal is a PENABLE signal associated with a write command.

18. A method as claimed in claim 13, wherein the first clock signal is a system clock of the integrated circuit.

19. A method as claimed in claim 13, wherein the second clock signal is an interface clock of an interface associated with the integrated circuit.

20. An electronic device comprising a synchronizing circuit as claimed in claim 1.

21. A communications device comprising a synchronizing circuit as claimed in claim 1.

22. A portable telephone device comprising a synchronizing circuit as claimed in claim 1.

23. An audio device comprising a synchronizing circuit as claimed in claim 1.

24. A computer device comprising a synchronizing circuit as claimed in claim 1.
